(19) United States
(12) Patent Application Publication
(10) Pub. No.: US 2009/0250735 A1
(43) Pub. Date: Oct. 8, 2009

(54) SEMICONDUCTOR MEMORY

(75) Inventor: Yoshiaki Asao, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/408,553

(22) Filed: Mar. 20, 2009

(30) Foreign Application Priority Data
Apr. 7, 2008 (JP) 2008-0099449

(51) Int. Cl. H01L 27/115

(52) U.S. Cl. 257/295; 257/E27.104

(57) ABSTRACT

A semiconductor memory according to an embodiment of the present invention including first and second adjacent bit lines extending in a first direction and provided in the same interconnect layer, an active provided in a memory cell array, a first and second adjacent word lines extending in a second direction intersecting the first direction, a cell group having two transistor provided in the active region and two resistive storage element, wherein the active region has a striped structure, and extends from one end of the memory cell array to the other.

### CROSS-REFERENCE TO RELATED APPLICATIONS

This application is based upon and claims the benefit of priority from prior Japanese Patent Application No. 2008-099449, filed Apr. 7, 2008, the entire contents of which are incorporated herein by reference.

### BACKGROUND OF THE INVENTION

1. Field of the Invention

The present invention relates to a semiconductor memory, such as a resistance-change semiconductor memory with a resistive storage element.

2. Description of the Related Art

Recently, attention has been directed toward a semiconductor memory in which an element having a varying resistance is used as a storage element, such as a magnetoresistive random access memory (MRAM) or a phase-change random access memory (PCRAM). The advantages of the MRAM include nonvolatility, high-speed operation, high integration capability and high reliability, and the MRAM is therefore being developed in the expectation that it will be replace, for example, a static RAMs (SRAMs) or a dynamic RAMs (DRAMs). The MRAM uses a magnetoresistive element called a magnetic tunnel junction (MTJ) having a structure in which an insulating film is interposed between two ferromagnetic materials. The MTJ element has a fixed direction of magnetization in one ferromagnetic layer (magnetization invariable layer) and a freely reversible direction of magnetization in the other ferromagnetic layer (magnetization free layer), and thus functions as a storage element.

What is called a spin-injection MRAM has been developed, and is attracting much attention, in which magnetization inversion caused by spin-polarized current injection is utilized as a means of writing to the MRAM (e.g., refer to U.S. Pat. No. 5,695,864). In this method, the amount of current necessary for the spin-injection magnetization inversion (inversion threshold current) is prescribed by the density of a current flowing through an MTJ element (magnetoresistive element), so that the inversion threshold current decreases together with the reduction in the area of the MTJ element. That is, the inversion threshold current is also scaled, and the spin-injection MRAM is therefore regarded as a prospective technique that makes it possible to obtain a high-capacity semiconductor memory.

Writing to the spin-injection MRAM is achieved by the making of a write current greater than or equal to the inversion threshold current flow to the MTJ element, and data to be written is determined by the direction of the write current flowing through the MTJ element. For example, in a general 1Tr+1MTJ memory cell, an MTJ element has one end connected to a first bit line and the other end connected to one source/drain of a metal-insulator-semiconductor (MIS) transistor, and the other source/drain of the MIS transistor is connected to a second bit line.

In a memory cell configured to have such connections, the first and second bit lines are formed in different interconnect layers. Thus, this memory has problems such as increased interconnects for bit line formation, increased manufacturing costs and an increased period required for chip production as compared with other semiconductor memories such as the DRAM.

And also, process margin is one problem. In general, cell groups each composed of one memory cell or two memory cells are provided in one active region. The active region has an island-shaped structure enclosed by an isolation region. Such an island-shaped active region creates difficulty in ensuring a process margin.

### BRIEF SUMMARY OF THE INVENTION

A semiconductor memory according to an embodiment of the present invention comprising: first and second adjacent bit lines extending in a first direction and provided in the same interconnect layer; an active region extending in the first direction and provided in a memory cell array; first and second adjacent word lines extending in a second direction intersecting the first direction; a first transistor having first and second source/drain diffusion layers provided in the active region, a first gate insulating film provided on the surface of the active region between the first and second source/drain diffusion layers, and a first gate electrode connected to the first word line and provided on the first gate insulating film; a second transistor having the second source/drain diffusion layer shared with the first transistor, a third source/drain diffusion layer provided in the active region, a second gate insulating film provided on the surface of the active region between the second and third source/drain diffusion layers, and a second gate electrode connected to the second word line and provided on the second gate insulating film; a first resistive storage element which has one end connected to the second bit line and the other end connected to the first source/drain diffusion layer and which is provided under the second bit line above the first source/drain diffusion layer; a second resistive storage element which has one end connected to the second bit line and the other end connected to the third source/drain diffusion layer and which is provided under the second bit line above the third source/drain diffusion layer; and an intermediate interconnection which is connected to the first bit line and the second source/drain diffusion layer and which is disposed between the first and second word lines across the first and second bit lines, wherein the active region has a striped structure extending in the first direction, and extends from one end of the memory cell array to the other.

A semiconductor memory of an aspect of the present invention comprising: first and second bit lines extending in a first direction and adjacently provided in the same interconnection layer; first and second active regions having a striped structure extending in the first direction and adjacently provided in a semiconductor substrate; first and second adjacent word lines extending in a second direction intersecting the first direction; a first transistor having first and second source/drain diffusion layers provided in the second active region, a first gate insulating film provided on the surface of the second active region between the first and second source/drain diffusion layers, and a first gate electrode connected to the first word line and provided on the first gate insulating film; a second transistor having the second source/drain diffusion layer shared with the first transistor, a third source/drain diffusion layer provided in the second active region, a second gate insulating film provided on the surface of the second active region between the second and third source/drain diffusion layers, and a second gate electrode connected to the second word line and provided on the second gate insulating film; a first resistive storage element which has one end connected to the second bit line and the other end connected to the first source/drain diffusion layer and which is provided under the second bit line above the first source/drain diffusion layer; a second resistive storage element which has one end connected to the second bit line and the other end connected to the third source/drain diffusion layer and which is provided under the second bit line above the third source/drain diffusion layer; a first intermediate interconnection which is connected to the first bit line and the second source/drain diffusion layer and which is disposed between the first and second word lines over the first and second active regions; third and fourth adjacent word lines extending in a direction intersecting the first and second active regions; a third transistor having fourth and fifth source/drain diffusion layers provided in the first active region, a third gate insulating film provided on the surface of the first active region between the fourth and fifth source/drain diffusion layers, and a third gate electrode connected to the third word line and provided on the third gate insulating film; a fourth transistor having the fifth source/drain diffusion layer shared with the third transistor, a sixth source/drain diffusion layer provided in the first active region, a fourth gate insulating film provided on the surface of the first active region between the fifth and sixth source/drain diffusion layers, and a fourth gate electrode connected to the fourth word line and provided on the fourth gate insulating film; a third resistive storage element which has one end connected to the first bit line and the other end connected to the fourth source/drain diffusion layer and which is provided under the first bit line above the fourth source/drain diffusion layer; a fourth resistive storage element which has one end connected to the first bit line and the other end connected to the sixth source/drain diffusion layer and which is provided under the first bit line above the sixth source/drain diffusion layer; and a second intermediate interconnection which is connected to the second bit line and the fifth source/drain diffusion layer and which is disposed between the third and fourth word lines over the first and second active regions.

A semiconductor memory of an aspect of the present invention comprising: first and second bit lines extending in a first direction and adjacently provided in the same interconnection layer; first and second active regions having a striped structure extending in the first direction and adjacently provided in a semiconductor substrate; first and second adjacent word lines extending in a second direction intersecting the first direction; a first transistor having first and second source/drain diffusion layers provided in the second active region, a first gate insulating film provided on the surface of the second active region between the first and second source/drain diffusion layers, and a first gate electrode connected to the first word line and provided on the first gate insulating film; a second transistor having the second source/drain diffusion layer shared with the first transistor, a third source/drain diffusion layer provided in the second active region, a second gate insulating film provided on the surface of the second active region between the second and third source/drain diffusion layers, and a second gate electrode connected to the second word line and provided on the second gate insulating film; a first resistive storage element which has one end connected to the second bit line and the other end connected to the first source/drain diffusion layer and which is provided under the second bit line above the first source/drain diffusion layer; a second resistive storage element which has one end connected to the second bit line and the other end connected to the third source/drain diffusion layer and which is provided under the second bit line above the third source/drain diffusion layer; a first intermediate interconnection which is connected to the first bit line and the second source/drain diffusion layer and which is disposed between the first and second word lines over the first and second active regions; a third bit line which is provided in the same interconnect layer as the first and second bit lines and which extends in the first direction and which is adjacent to the second bit line; a third active region which has striped structure extending in the first direction and which is provided in the semiconductor substrate adjacently to the second active region; third and fourth adjacent word lines extending in the second direction; a third transistor having fourth and fifth source/drain diffusion layers provided in the third active region, a third gate insulating film provided on the surface of the third active region between the fourth and fifth source/drain diffusion layers, and a third gate electrode connected to the third word line and provided on the third gate insulating film; a fourth transistor having the fifth source/drain diffusion layer shared with the third transistor, a sixth source/drain diffusion layer provided in the third active region, a fourth gate insulating film provided on the surface of the third active region between the fifth and sixth source/drain diffusion layers, and a fourth gate electrode connected to the fourth word line and provided on the fourth gate insulating film; a third resistive storage element which has one end connected to the third bit line and the other end connected to the fourth source/drain diffusion layer and which is provided under the third bit line above the fourth source/drain diffusion layer; a fourth resistive storage element which has one end connected to the third bit line and the other end connected to the sixth source/drain diffusion layer and which is provided under the third bit line above the sixth source/drain diffusion layer; and a second intermediate interconnection which is connected to the second bit line and the fifth source/drain diffusion layer and which is disposed between the third and fourth word lines over the second and third active regions.

### BRIEF DESCRIPTION OF THE SEVERAL VIEWS OF THE DRAWING

FIG. 1 is an equivalent circuit diagram of one cell group in a semiconductor memory according to an embodiment of the present invention;

FIG. 2 is an equivalent circuit diagram of a memory cell array in an MRAM according to a first embodiment;

FIG. 3 is a layout diagram of the memory cell array in the MRAM according to the first embodiment;

FIG. 4 is a sectional view along line A-A of FIG. 3;

FIG. 5 is a sectional view along line B-B of FIG. 3;

FIG. 6 is a plan view for stepwise explanation of the layout of the memory cell array;

FIG. 7 is a plan view for stepwise explanation of the layout of the memory cell array;

FIG. 8 is a plan view for stepwise explanation of the layout of the memory cell array;

FIG. 9 is a schematic view showing the structure of a magnetoresistive effect element;

FIG. 10 is a schematic view showing the structure of the magnetoresistive effect element;

FIG. 11 is a diagram showing a comparative example to the MRAM according to the first embodiment;

FIG. 12 is a sectional view along line A-A of FIG. 3, in an MRAM according to the second embodiment;

FIG. 13 is a sectional view along line B-B of FIG. 3, in the MRAM according to the second embodiment;

FIG. 14 is a diagram showing one step of the manufacturing process of the MRAM according to the second embodiment;

FIG. 15 is an equivalent circuit diagram of a memory cell array in an MRAM according to a third embodiment; and

FIG. 16 is a layout diagram of the memory cell array in the MRAM according to the third embodiment.

### DETAILED DESCRIPTION OF THE INVENTION

Hereinafter, embodiments of the present invention will be described in detail with reference to the drawings.

### 1. Outline

The embodiments of the present invention relate to a semiconductor memory with a resistive storage element. The resistive storage element is an element which stores data in a nonvolatile manner by using the change in resistance with the supply of a current or voltage. The semiconductor memory with such a resistive storage element is, for example, a magnetoresistive random access memory (MRAM) with a magnetoresistive effect element.

The semiconductor memory in the present embodiments is a semiconductor memory in which a pair of bit lines connected to both ends of a memory cell is provided in the same interconnect layer, and is characterized in that active regions where the memory cells or cell groups are provided are striped.

This active region extends from one end of the memory cell array to the other in the memory cell array where a plurality of memory cells or cell groups are provided. One active region is shared by a plurality of cell groups (memory cells) arranged in a direction in which the active region extends.

According to this structure, a surface region of a semiconductor substrate in the present embodiments has a line-and-space pattern in which a plurality of active regions and a plurality of isolation regions alternately adjoin one another. Thus, it is easier to ensure a process margin than in a conventional surface region of a semiconductor substrate which is formed by an island-shaped active region enclosed by an isolation region.

Consequently, according to the embodiments of the present invention, it is possible to provide a semiconductor memory capable of improving a process margin.

### 2. Embodiments

First to third embodiments of the present invention will be described below with reference to the drawings. While a magnetoresistive random access memory (MRAM) is described by way of example in the embodiments of the present invention, the present invention is not limited thereto. For example, the present invention may also be applicable to a phase-change random access memory (PCRAM) with a storage element that uses the change of a crystalline phase, or a resistive random access memory (ReRAM) with a storage element that changes its resistance by the application of a voltage.

### [1] First Embodiment

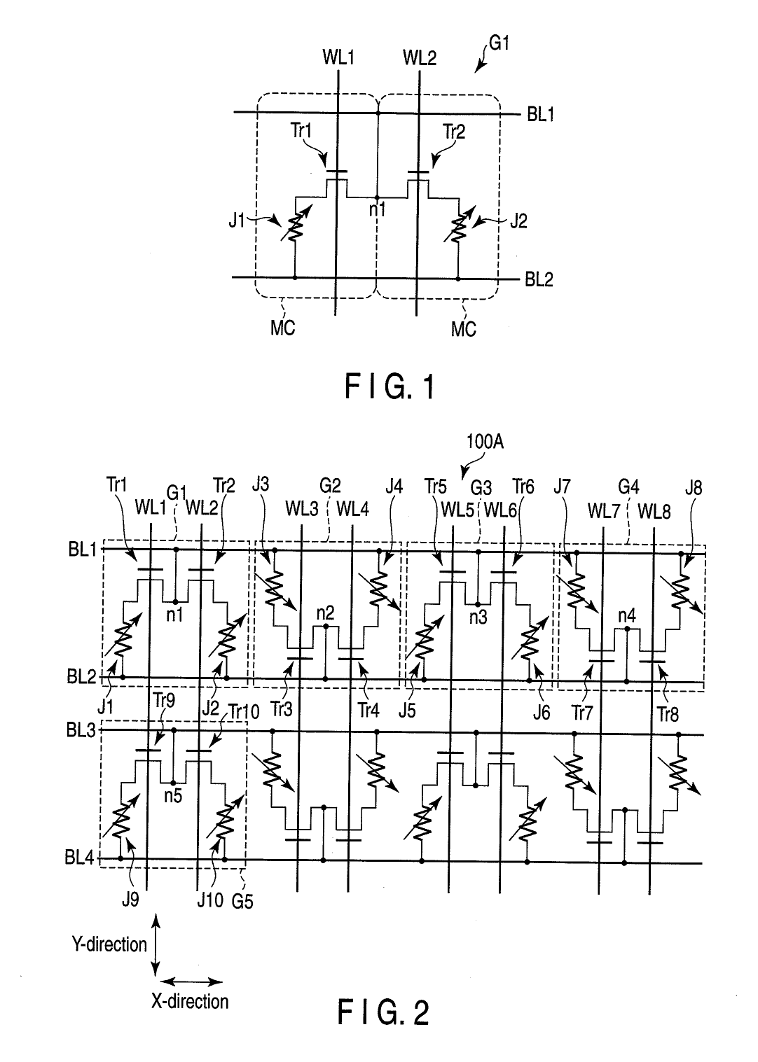

A semiconductor memory according to the first embodiment is described with reference to FIGS. 1 to 9.

(1) Circuit Configuration

The circuit configuration of a memory cell array in the semiconductor memory (MRAM) according to the first embodiment of the present invention is described with FIGS. 1 and 2.

FIG. 1 shows an equivalent circuit of one cell group in the MRAM according to the present embodiment. As shown in FIG. 1, one memory cell MC has what is called a 1Tr+1MTJ configuration comprising one field effect transistor (MIS transistor) as a switch element and one magnetoresistive effect element (MTJ element) as a resistive storage element. One cell group G1 comprises adjacent two memory cells MC.

A specific circuit configuration of cell group G1 is as follows: One end of a first MTJ element J1 is connected to one end of a current path of a first MIS transistor Tr1, and the other end of the first MTJ element J1 is connected to a second bit line BL2. The other end of the current path of the first MIS transistor Tr1 is connected to a node n1. A gate of the first MIS transistor Tr1 is connected to a first word line WL1. One end of a second MTJ element J2 is connected to one end of a current path of a second MIS transistor Tr2, and the other end of the second MTJ element J2 is connected to the second bit line BL2. The other end of the current path of the second MIS transistor Tr2 is connected to node n1. A gate of the second MIS transistor Tr2 is connected to a second word line WL2. Further, node n1 to which both the first and second MIS transistors Tr1, Tr2 are connected is connected to a first bit line BL1.

FIG. 2 shows an equivalent circuit of the memory cell array in the MRAM according to the present embodiment. As shown in FIG. 2, a memory cell array 100A in the present embodiment is composed of a plurality of cell groups. In the memory cell array shown in FIG. 2, the cell groups adjacent in an X-direction are arranged to have a mirror-image relation, while the cell groups adjacent in a Y-direction are arranged to have a translational relation. Here, the mirror-image relation means a relation wherein adjacent cell groups are line-symmetrical in a direction (X-direction) in which the bit lines extend, or a relation wherein a cell group forms an inversion of a cell group adjacent thereto in the Y-direction. The translational relation means translational symmetry.

The configuration of the memory cell array 100A is more specifically described below. In addition, cell group G1 in FIG. 2 is similar in configuration to cell group G1 in FIG. 1 and is therefore not described in detail.

In the memory cell array 100A in FIG. 2, a second cell group G2 adjacent to cell group G1 in the X-direction has the following circuit configuration. One end of a third MTJ element J3 is connected to one end of a current path of a third MIS transistor Tr3, and the other end of the third MTJ element J3 is connected to the first bit line BL1. The other end of the third MIS transistor Tr3 is connected to a node n2. A gate of the third MIS transistor Tr3 is connected to a word line WL3. One end of a fourth MTJ element J4 is connected to one end of a current path of a fourth MIS transistor Tr4, and the other end of the fourth MTJ element J4 is connected to the first bit line BL1. The other end of the current path of the fourth MIS transistor Tr4 is connected to node n2. A gate of the fourth MIS transistor Tr4 is connected to a fourth word line WL4. Further, node n2 to which The third and fourth MIS transistors Tr3, Tr4 are linked is connected to the second bit line BL2.

Cell groups G1, G2 adjacent in the X-direction are both connected to the same pair of bit lines BL1, BL2, but the connection between the bit lines BL1, BL2 and cell group 2 is inverse to the connection between the bit lines BL1, BL2 and cell group G1. That is, shared node n1 is connected to the first bit line BL1 in cell group G1, while shared node n2 is connected to the second bit line BL2 in cell group G2. Thus, cell groups G1, G2 adjacent in the X-direction have the mirror-image relation.

Similarly to the first cell group G1, a third cell group G3 has two MTJ elements J5, J6 and two MIS transistors Tr5, Tr6. Cell group G3 adjacent to cell group G2 in the X-direction has a mirror-image relation with cell group G2, and is connected to the pair of bit lines BL1, BL2 similarly to cell group G1.

Similarly to the second cell group G2, a fourth cell group G4 has two MTJ elements J7, J8 and two MIS transistors Tr7, Tr8. Cell group G4 adjacent to cell group G3 in the X-direction has a mirror-image relation with cell group G3, and is similar in configuration to cell group G2. Thus, in the X-direction of the memory cell array 100A, a cell group similar in configuration to cell group G1 and a cell group similar in configuration to cell group G2 are alternately arranged.

A fifth cell group G5 adjacent to cell group G1 in the Y-direction has the following circuit configuration. One end of a ninth MTJ element J9 is connected to one end of a current path of a ninth MIS transistor Tr9, and the other end of the ninth MTJ element J9 is connected to the fourth bit line BL4. The other end of the current path of the ninth MIS transistor Tr9 is connected to a node n5, and a gate of the ninth MIS transistor Tr9 is connected to the first word line WL1. One end of a tenth MTJ element J10 is connected to one end of a current path of a tenth MIS transistor Tr10, and the other end of the tenth MTJ element J10 is connected to the fourth bit line BL4. The other end of the current path of the tenth MIS transistor Tr10 is connected to node n5, and a gate of the tenth MIS transistor Tr10 is connected to the second word line WL2. Further, node n5 to which the ninth and tenth MIS transistors Tr9, Tr10 are linked is connected to a third bit line BL3.

Cell groups G1, G5 adjacent in the Y-direction share the same word lines WL1, WL2, and Cell group G1 between the pair of bit lines BL1, BL2 and Cell group G5 between the pair of bit lines. BL3, BL4 are arranged in the same direction. Thus, the bit line BL1 to which shared node n1 is connected, the second bit line BL2 to which MTJ elements J1, J2 are connected, bit line BL3 connected to shared node n5, and bit line BL4 to which MTJ elements J9, J10 are connected are arranged in order in the Y-direction of the memory cell array 100A. That is, in the Y-direction of the memory cell array, the bit lines to which the shared nodes are connected and the bit lines to which the MTJ elements are connected are alternately arranged along the Y-direction. Thus, cell groups G1, G5 adjacent in the Y-direction have the translational relation.

In this memory cell array 100A, a driver/sinker (not shown) for data writing and a sense amplifier used for data reading are connected to each of bit lines BL1 to BL4 on one end and the other, respectively. Moreover, a word line driver (not shown) for selecting a predetermined word line is connected to each of word lines WL1 to WL8.

(2) Structure

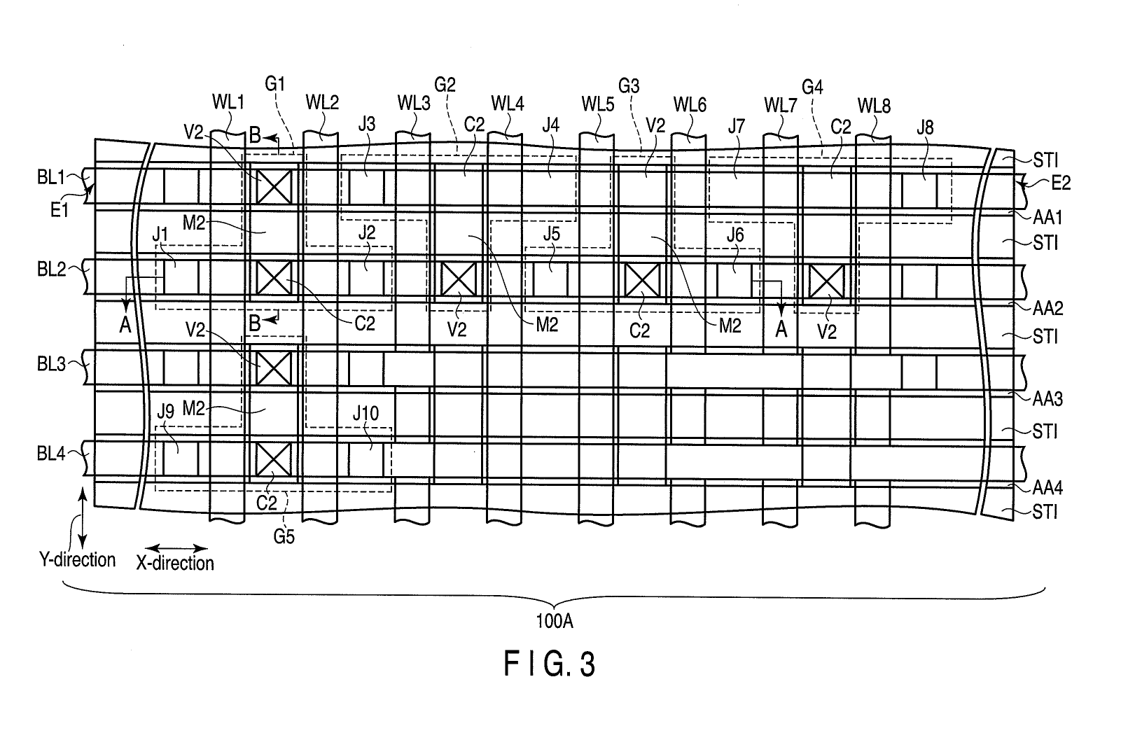

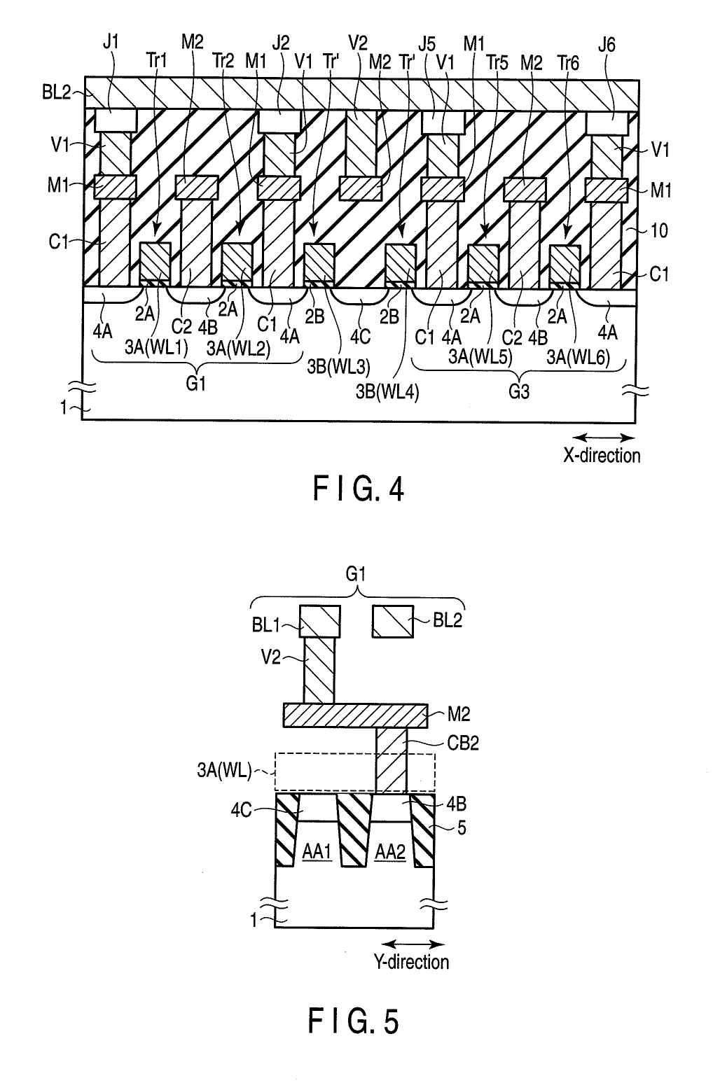

The structure of the memory cell array 100A shown in FIG. 2 is described with reference to FIGS. 3 to 5. FIG. 3 is a plan view showing the layout of the memory cell array 100A in FIG. 2. FIG. 4 is a sectional view along the line A-A of FIG. 2, and FIG. 5 is a sectional view along the line B-B of FIG. 2. Components of the respective cell groups are much the same. Therefore, the structure of cell group G1 is described below as a main example.

As shown in FIGS. 3 to 5, the memory cell array 100A is provided in a semiconductor substrate 1.

The first to fourth bit lines BL1 to BL4 are provided in the same interconnect layer in the memory cell array 100A, and extend in the same direction (e.g., X-direction). Moreover, two bit lines are adjacently arranged.

The first to fourth word lines WL1 to WL4 are provided in the same interconnect layer in the memory cell array 100A, and extend in a direction (e.g., Y-direction) intersecting the direction in which bit lines BL1, BL2 extend. Moreover, two word lines are adjacently arranged.

In the memory cell array 100A, a surface region of the semiconductor substrate 1 comprises a plurality of isolation regions STI, and first to fourth active regions AA1 to AA4 which are each interposed between two isolation regions STI. The isolation regions STI and active regions AA1 to AA4 extend from one end E1 of the memory cell array 100A to the other end E2 in same direction (e.g., X-direction) as the direction in which bit lines BL1 to BL4 extend. Active regions AA1 to AA4 are arranged under bit lines BL1 to BL4 via an interlayer insulating film 10, respectively.

As shown in FIG. 3, each of cell groups G1 to G5 is laid out with a T-shaped planer structure (regions enclosed by broken lines). The size of one memory cell constituting the cell group is 8F² (F is a future size). In addition, a plurality of cell groups are arranged in the semiconductor substrate 1 (memory cell array) in the example shown in FIGS. 3 to 5. However, this is not a limitation. It should be understood that one cell group G1 may be only provided in one active region AA2 extending from one end E1 of the semiconductor substrate 1 (memory cell array) to the other E2.

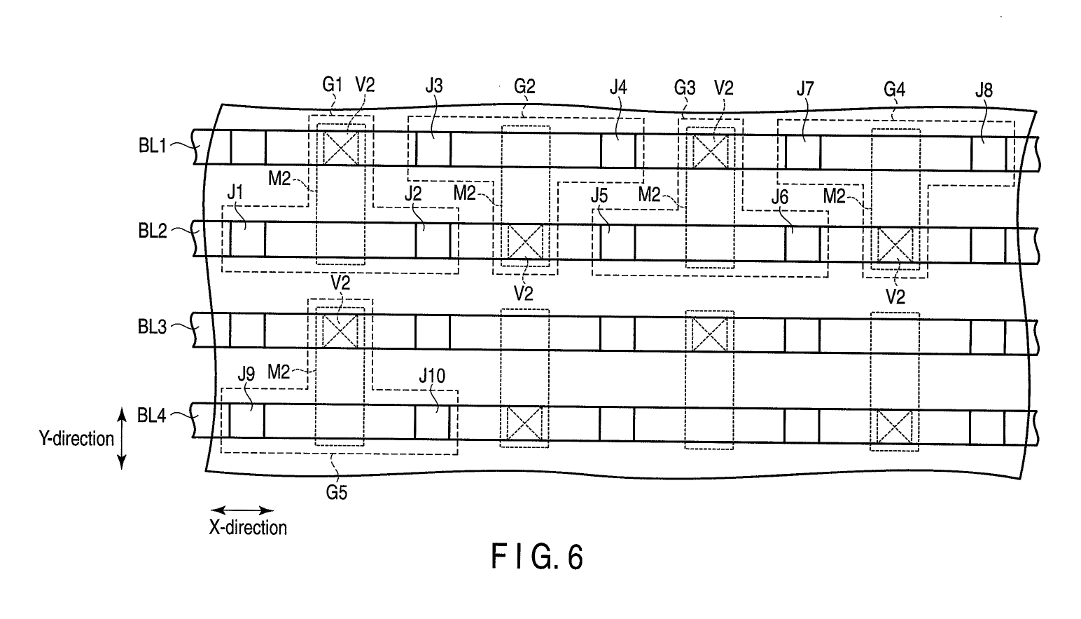

The structure of each interconnect layer between the bit line and the word line is described below step by step with reference to FIGS. 6 to 8 together with FIGS. 3 to 5. FIGS. 6 to 8 are shows plan views of the interconnect layers.

FIG. 6 shows the layout of the interconnect layer in which the bit lines BL1 to BL4 are provided. As shown in FIGS. 4 to 6, bit lines BL1 to BL4 are arranged adjacently to one another in the Y-direction. A pair of bit lines connected to one cell group is provided in the same interconnect layer in this manner, thereby enabling a reduction in process cost without increasing the area of the memory cell.

As shown in FIGS. 4 and 6, the first and second MTJ elements J1, J2 in cell group G1 are provided in direct contact with the second bit line BL2. The third and fourth MTJ elements J3, J4 in cell group G2 are provided in direct contact with the first bit line BL1. The fifth and sixth MTJ elements J5, J6 in cell group G3 are provided in direct contact with the second bit line BL2 as in cell group G1. The seventh and eighth MTJ elements J7, J8 in cell group G4 are provided in direct contact with bit line BL1 as in cell group G2. Further, the ninth and tenth MTJ elements J9, J10 in cell group G5 are provided in direct contact with the third bit line BL3. In addition, electrodes or contacts may be provided between MTJ elements J1 to J10 and bit lines BL1 to BL4.

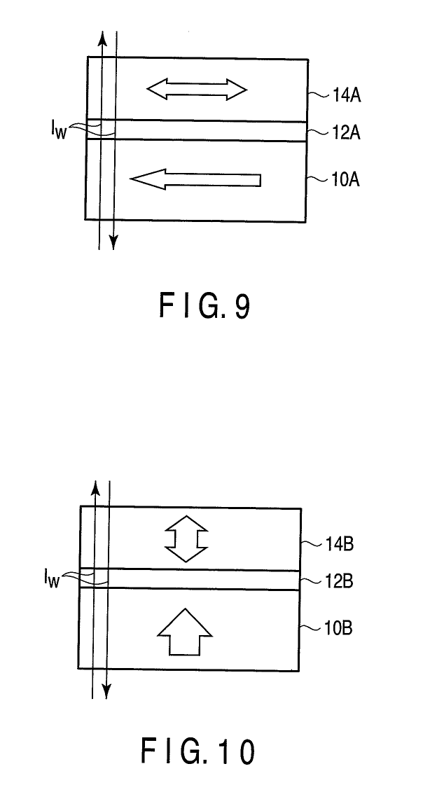

MTJ elements J1 to J10 are magnetoresistive effect elements that utilize magnetic tunnel junction. FIGS. 9 and 10 schematically show the sectional structure of MTJ element J1.

MTJ elements J1, J2 include, for example, as shown in FIGS. 9 and 10, magnetization invariable layers (reference layer) 10A, 10B having an invariable direction of magnetization, magnetization free layers (storage layers) 14A, 14B having a direction of magnetization that changes in accordance with data, and nonmagnetic layers 12A, 12B provided between magnetization invariable layers 10A, 10B and magnetization free layers 14A, 14B. Ferromagnetic materials, for example, are used for magnetization invariable layers 10A, 10B and magnetization free layers 14A, 14B. Insulators, for example, are used for the nonmagnetic layers 12A, 12B, and the nonmagnetic layers 12A, 12B function as tunnel barrier layers.

MTJ elements J1 to J10 may have a single junction structure with one nonmagnetic layer providing one magnetic tunnel junction. Alternatively, MTJ elements J1 to J10 may have a double junction structure with two nonmagnetic layers providing two magnetic tunnel junctions.

The MTJ element of the single junction structure may be a bottom pin type in which a magnetization free layer is in contact with a bit line and in which a magnetization invariable layer is disposed on the side of the semiconductor substrate 1, or may be a top pin type in which a magnetization invariable layer is in contact with a bit line and in which a magnetization free layer is disposed on the side of the semiconductor substrate 1.

The MTJ element of the double junction structure comprises a first magnetization invariable layer, a second magnetization invariable layer, one magnetization free layer provided between the first and second magnetization invariable layers, a first nonmagnetic layer provided between the first magnetization invariable layer and the magnetization free layer, and a second nonmagnetic layer provided between the second magnetization invariable layer and the magnetization free layer.

In a parallel magnetization MTJ element, the direction of magnetization of magnetization invariable layer 10A and magnetization free layer 14A is parallel to a film surface, for example, as shown in FIG. 9. In perpendicular magnetization MTJ elements J1 to J10, the direction of magnetization of magnetization invariable layer 10B and magnetization free layer 14B is perpendicular to a film surface, for example, as shown in FIG. 10.

In the parallel magnetization MTJ element, the magnetization invariable layer 10A may be provided on an antiferromagnetic layer, and the direction of magnetization of magnetization invariable layer (pinned layer) 10A may be fixed by an antiferromagnetic layer (pin layer).

The planar shape of MTJ elements J1 to J10 is not limited to the shown square shape. For example, the planar shape of the MTJ elements may be rectangular, elliptical, circular, hexagonal, rhombic, parallelogrammatic, cross-shaped or bean-shaped (concave). Moreover, instead of the MTJ element, a resistive storage element that utilizes a change in crystalline phase or a change in resistance may be used.

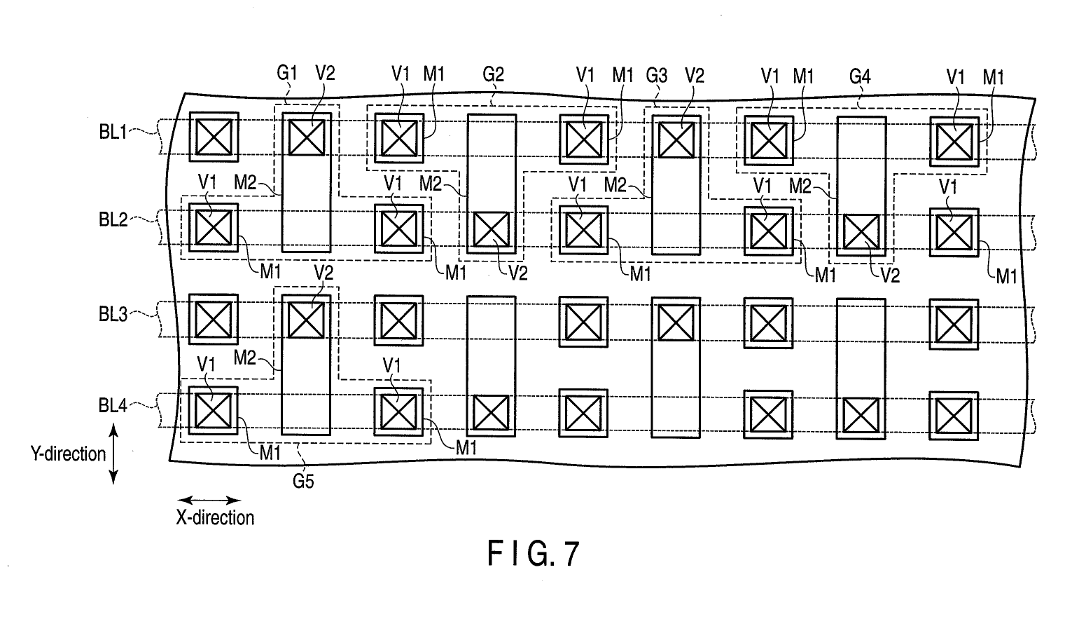

FIG. 7 shows the layout of an intermediate interconnection located between the layer where bit lines BL1 to BL4 are provided and the layer where word lines WL1 to WL8 are provided. As shown in FIGS. 4, 5 and 7, intermediate interconnection M1 are provided under MTJ elements J1 and J2, and MTJ elements J1 and J2 are electrically connected to the intermediate interconnection M1 through via contacts V1. Via contacts V1 also function as, for example, bottom electrodes for MTJ elements J1, J2.

Furthermore, an intermediate interconnection M2 serving as a leader interconnection is provided between two intermediate interconnection M1 adjacent in the X-direction. The intermediate interconnection M2 will hereinafter be called the leader interconnection M2. The leader interconnection M2 extends in the Y-direction, and is drawn from a position under a bit line to a position under a bit line adjacent to the former bit line. In cell group G1, the leader interconnection M2 is drawn from a position under second bit line BL2 to a position under bit line BL1, and connected to bit line BL1 through a via contact V2, for example, as shown in FIG. 5. Similarly, the leader interconnection M2 in each of cell groups G2 to G5 is disposed across two bit lines (two active regions). Further, the leader interconnection M2 is connected through via contact V2 to one of a pair of bit lines to which the MTJ element of each cell group is not connected.

The pair of bit lines and the leader interconnection are connected in a manner as described above, so that via contact V2 of cell group G1 is provided under bit line BL1, and via contact V2 of cell group G2 is provided under bit line BL2. Further, via contact V2 of cell group G3 is provided under the bit line BL1 as in cell group G1, and via contact V2 of cell group G4 is provided under bit line BL2 as in cell group G2. As a result, via contacts V2 of cell groups G1 to G4 adjacent in the X-direction are arranged in a zigzag form along the X-direction between two bit lines BL1, BL2.

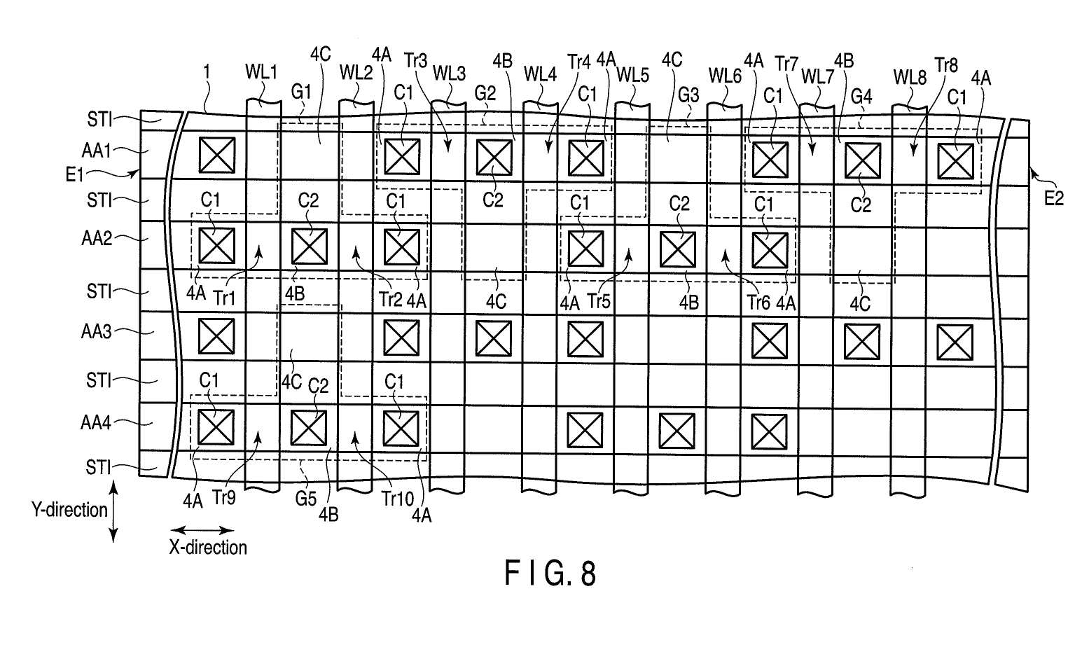

FIG. 8 shows word lines WL1 to WL8 and the layout of the surface region of the semiconductor substrate 1. As shown in FIGS. 4, 5 and 8, the surface region of the semiconductor substrate 1 comprises the plurality of isolation regions STI extending in the X-direction, and the plurality of active regions AA1 to AA4 extending in the X-direction. The isolation regions STI and active regions AA1 to AA4 are arranged in the semiconductor substrate 1 alternately along the Y-direction. One active region AA1 is interposed between two isolation regions STI.

For example, an isolation insulating film 5 of a shallow trench isolation (STI) structure is embedded in the isolation region STI as shown in FIG. 4, such that active regions AA1 to AA4 adjacent in the Y-direction are electrically isolated from each other. Active regions AA1 to AA4 have a striped structure, and extend from one end E1 of the memory cell array to the other E2 along the X-direction (bit line extending direction). In addition, the striped structure mentioned in the present embodiment means a linear structure extending along one direction.

Word lines WL1 to WL8 extend in the Y-direction, and intersect active regions AA1 to AA4 extending in the X-direction. Each of the first and second word lines WL1, WL2 of cell group G1 is disposed between a first contact C1 and a second contact C2. Similarly, each of the word lines WL3 to WL8 connected to the other cell groups is disposed between two contacts C1, C2. In such layout of word lines WL1 to WL8 and contacts C1, C2, one leader interconnection M2 is disposed between two word lines WL1, WL2.

As described above, one memory cell in the present embodiment has the 1Tr+1MTJ configuration. MIS transistors Tr1 to Tr10 constituting this memory cell are provided where active regions AA1 to AA4 intersect word lines WL1 to WL8.

In cell group G1, the first and second MIS transistors Tr1, Tr2 are provided on the second active region AA2 under the second bit line BL2. MIS transistors Tr1, Tr2 use, as a gate insulating film, an insulating film 2A provided on the surface of active region AA2. MIS transistors Tr1, Tr2 have a gate electrode 3A provided on the gate insulating film 2A, and source/drain diffusion layers 4A, 4B provided in active region AA2 (semiconductor substrate 1).

Gate electrode 3A extends in the Y-direction, and is shared by a plurality of MIS transistors adjacent in the Y-direction. Gate electrodes 3A function as the first and second word lines WL1, WL2.

Source/drain diffusion layer (first and third source/drain diffusion layers) 4A is connected to contact C1 embedded in the interlayer insulating film 10. Further, source/drain diffusion layer 4A is connected to MTJ element J1, J2 located above source/drain diffusion layer 4A through contact C1, the intermediate interconnection M1 and via V1.

Source/drain diffusion layer (second source/drain diffusion layer) 4B is provided in active region AA2 between word lines WL1, WL2. Source/drain diffusion layer 4B is shared by the transistors Tr1, Tr2, and serves as shared node n1 of cell group G1. Source/drain diffusion layer 4B is connected to the leader interconnection M2 via contact C2. Further, in cell group C1, the leader interconnection M2 is connected to bit line BL1, as described above.

In cell group G2, the third and fourth MIS transistors Tr3, Tr4 are provided on the first active region AA1. The MIS transistors Tr3, Tr4 have the gate insulating film 2B on the surface of active region AA1, the gate electrode 3B provided on the gate insulating film 2B, source/drain diffusion layers 4A, 4B provided in active region AA1 (semiconductor substrate 1).

A gate electrode 3B extends in the Y-direction, and is shared by a plurality of MIS transistors adjacent in the Y-direction. Gate electrodes 3B function as the third and fourth word lines WL3, WL4.

Source/drain diffusion layer (fourth and sixth source/drain diffusion layers) 4A is connected to contact C1 embedded in the interlayer insulating film 10. Further, source/drain diffusion layer 4A is connected to MTJ element J3, J4 located above source/drain diffusion layer 4A through contact C1, the intermediate interconnection M1 and via V1.

Source/drain diffusion layer (fifth source/drain diffusion layer) 4B is provided in active region AA1 between word lines WL3, WL4. Source/drain diffusion layer 4B is shared by MIS transistors Tr3, Tr4, and serves as shared node n2 of cell group G2. Source/drain diffusion layer 4B is connected to the leader interconnection M2 via contact C2. Further, in cell group G2, the leader interconnection M2 is connected to bit line BL2, as described above.

In the third cell group G3, the fifth and sixth MIS transistors Tr5, Tr6 are provided on the second active region AA2, as in the configuration of the first cell group G1. In the fourth cell group G4, the seventh and eighth MIS transistors Tr7, Tr8 are provided on the first active region AA1, as in the configuration of the second cell group G2. Moreover, in the fifth cell group G5 adjacent to cell group G1 in the Y-direction, the ninth and tenth MIS transistors Tr9, Tr10 are provided on the fourth active region AA4, and share gate electrode 3A (word lines WL1, WL2) with the first and second MIS transistors Tr1, Tr2.

Thus, active regions AA1 to AA2 are striped, so that the elements in the active regions are not isolated from each other by the insulating film in the X-direction. As a result, the cell groups having the translational relation among the cell groups arranged in the X-direction, such as the first cell group G1 and the third cell group G3, have MIS transistors Tr1, Tr2, Tr5, Tr6 on the same active region AA2.

Furthermore, between two cell groups (e.g., cell groups G1, G3) having the MIS transistors in the same active region, two word lines WL3, WL4 (gate electrodes 3B) that are not connected to these cell groups G1, G3 pass. In the present embodiment, a diffusion layer (impurity region) 4C is provided in the active region between the two word lines WL3, WL4 at a location where these word lines pass.

The MRAM according to the first embodiment of the present invention is characterized in that the active regions where the memory cells and the cell groups are provided have a striped structure extending in the X-direction.

When active regions AA1 to AA4 are striped as in the present embodiment, the surface region of the semiconductor substrate 1 has what is called a line-and-space pattern in which each of active regions AA1 to AA4 is interposed between two isolation regions STI.

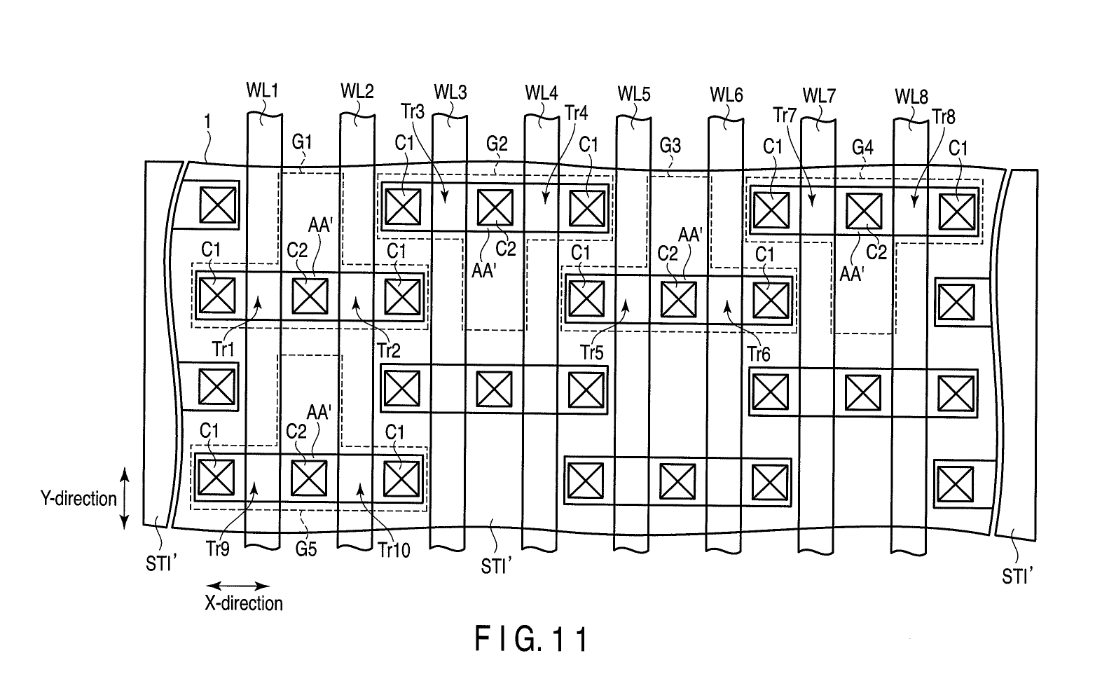

Here, the embodiment of the present invention is compared with another technique with reference to FIGS. 8 and 11. FIG. 11 is a plan view showing one example of the layout of the active regions. In FIG. 11, interconnect layers are provided as in the configuration shown in FIGS. 6 and 7 so that the memory cell array shown in FIG. 2 can be configured.

In the example shown in FIG. 11, active regions AA′ are isolated from each other for the respective cell groups, and have an island-shaped structure enclosed by the isolation region. As shown in FIG. 11, when active regions AA′ have the island-shaped structure, size designing, patterning and fabrication of active regions AA′ have to be performed in consideration of the process margin of the active regions AA adjacent in the Y-direction and X-direction.

On the other hand, as shown in FIG. 8, active regions AA in the MRAM according to the embodiment of the present invention have a striped structure extending in the X-direction, wherein the plurality of active regions AA1 to AA4 and the plurality of isolation regions STI alternate in the Y-direction in the memory cell array. In such a line-and-space pattern, dimensional designing, patterning and fabrication can be performed only considering the active regions adjacent in the Y-direction.

Thus, as shown in FIG. 8, one active region has the striped structure, such that the process margin can be improved as compared with the configuration shown in FIG. 11.

Consequently, according to the semiconductor memory in the first embodiment of the present invention, the process margin in its manufacturing process can be improved.

(3) Manufacturing Method

A method of manufacturing the MRAM according to the first embodiment of the present invention is described with reference to FIGS. 4 to 8.

First, as shown in FIGS. 4, 5 and 8, after a well region (not shown) of a first conductivity type is formed in a semiconductor substrate 1, a plurality of trenches having, for example, an STI structure and extending in the X-direction are formed in the semiconductor substrate 1, and an isolation insulating film 5 (e.g., a silicon oxide film) is embedded in the trenches. As a result, a plurality of isolation regions STI extending in the X-direction and a plurality of active regions AA1 to AA4 each interposed between two isolation regions adjacent in the Y-direction are formed in a surface region of the semiconductor substrate 1. That is, the active regions AA1 to AA4 have a striped structure extending in the X-direction, and the surface region of the semiconductor substrate 1 has a line-and-space pattern structure composed of active regions AA1 to AA4 (line patterns) and the isolation regions STI (space patterns).

In the fabrication (trench formation) of active regions AA1 to AA4, patterning and etching can be performed only considering the process margin in the Y-direction owing to the striped structure of active regions AA1 to AA4 extending in the X-direction.

Then, gate insulating films 2A, 2B are formed on the surfaces of active regions AA1 to AA4 (semiconductor substrate 1). A gate electrode material made of, for example, polysilicon is deposited on the surface region of the semiconductor substrate 1 by a chemical vapor deposition (CVD) method. Further, polysilicon is, for example, patterned by a photolithographic technique to extend polysilicon in the Y-direction, and processed by a reactive ion etching (RIE) method. Thus, gate electrodes 3A, 3B functioning as word lines WL1 to WL8 are formed on insulating films 2A, 2B. Gate electrodes 3A, 3B extend in the Y-direction, and therefore intersect active regions AA1 to AA4 extending in the X-direction.

Subsequently, source/drain diffusion layers 4A, 4B of a conductivity type (second conductivity type) opposite to the first conductivity type are formed in active regions AA1 to AA4 by, for example, an ion implantation method in a self-aligning manner using gate electrodes (word lines) 3A, 3B as masks. As a result, MIS transistors Tr1 to Tr10 constituting a memory cell MC are formed. In addition, when source/drain diffusion layers 4A, 4B are formed for the word lines (gate electrodes) in a self-aligning manner, diffusion layers (impurity regions) 4C are simultaneously formed in the first and third active regions AA1, AA3 between the first and second word lines WL1, WL2 and in the second and fourth active regions AA2, AA4 between the third and fourth word lines WL3, WL4.

Furthermore, an interlayer insulating film is formed on the semiconductor substrate 1 over the formed gate electrodes 3A, 3B. Then, first and second contacts C1, C2 are embedded in the interlayer insulating film so that these contacts are connected to source/drain diffusion layers 4A, 4B, respectively.

Then, as shown in FIGS. 4, 5 and 7, a metal material such as aluminum, copper or tungsten is deposited on the interlayer insulating film and on contacts C1, C2 by the CVD method or sputter method, and then an intermediate interconnection M1 is formed on contact C1 by using the photolithographic technique and the RIE method. At the same time, a leader interconnection M2 is formed on contact C2. The leader interconnection M2 is patterned and formed across two active regions (e.g., active regions AA2, AA4) between two word lines (e.g., between word lines WL1, WL2).

Then, a new interlayer insulating film is formed on the intermediate interconnection M1, the leader interconnection M2 and the former interlayer insulating film.

Furthermore, as shown in FIGS. 4 to 6, a via contact V1 is embedded in the interlayer insulating film into contact with the intermediate interconnection M1. Then, MTJ elements J1 to J10 are formed on via contact V1. Moreover, a via contact V2 is embedded in the interlayer insulating film into contact with the leader interconnection M2.

Subsequently, a metal material such as aluminum or copper is formed on the interlayer insulating film 10 by the CVD method or sputter method, and the metal material is processed by the photolithographic technique and the RIE method. As a result, bit lines BL1 to BL4 are formed so that bit lines BL1, BL3 is connected to via V2 and so that bit lines BL2, BL4 is connected to MTJ elements J1 to J10. Bit lines BL1 to BL4 are formed in such locations as to vertically overlap active regions AA1 to AA4.

A pair of bit lines is simultaneously formed in the same interconnect layer as described above, thereby enabling a reduction in process cost and in the period for chip production without increasing the area of the memory cell.

As described above, in the manufacturing method of the present embodiment, the active regions where the memory cells and the cell groups are formed are formed to have a striped structure. Thus, the surface region of the semiconductor substrate in the memory cell array has a line-and-space pattern composed of the active regions and the isolation regions, for which patterning and fabrication are easier.

Consequently, according to the first embodiment of the present invention, it is possible to provide a semiconductor memory capable of improving a process margin.

(4) Operation

A method of writing to/reading from the memory cell array 100A shown in FIG. 2 in the MRAM according to the first embodiment of the present invention is described below. For example, an MRAM identifies data by use of tunneling magnetoresistive effect. The tunneling magnetoresistive effect means the change in the tunnel resistance of a nonmagnetic layer (tunnel barrier film) interposed between ferromagnetic layers depending on whether the directions of magnetization of the magnetization invariable layer and the magnetization free layer in the MTJ element are parallel or antiparallel to each other. The resistance of the MTJ element is low when the directions of magnetization of the magnetization invariable layer and the magnetization free layer are parallel to each other, while the resistance value of the MTJ element is high when the directions of magnetization are antiparallel to each other. Whether data is “1” or “0” is recognized in accordance with whether the resistance of the MTJ element is high or low.

A spin-injection magnetization inversion technique, for example, is used for writing to the MRAM of the present embodiment. In the inversion of magnetization by spin injection (spin-transfer torque), electrons which are spin-polarized by the magnetic moment of the magnetization invariable layer (referred to as spin-polarized electrons) are injected into a recording layer, and the magnetization of the recording layer is inverted by the movement of spin angular momentum due to an exchange interaction between the spin-polarized electrons and electrons in the recording layer. That is, as shown in FIG. 9 or 10, a write current Iw is made to flow from magnetization invariable layers 10A, 10B to magnetization free layers 14A, 14B or from magnetization free layers 14A, 14B to magnetization invariable layers 10A, 10B. As a result, the direction of magnetization of magnetization free layers 14A, 14B as storage layers is antiparallel (e.g., data “0”) or parallel (e.g., data “1”) to the direction of magnetization of the magnetization invariable layers 10A, 10B, and the data is written to the MTJ element as a resistive storage element.

In this manner, a potential difference is applied across both ends of the MTJ element to make a write current greater than or equal to than a magnetization inversion threshold current flow. Accordingly, the direction of magnetization of the magnetization free layer is inverted, and the directions of magnetization of the magnetization invariable layer and the magnetization free layer are parallel or antiparallel to each other depending of flow direction of the write current. The resistance of the MTJ element is thus changed, such that the data “1”, “0” is written.

Writing to/reading from each of the memory cells MC constituting the memory cell array 100A are performed in the following manner: Out of a plurality of word lines WL1 to WL8, one word line to which a memory cell to write data to or read data from belongs to is selected, and the MIS transistor connected to this word line is turned on. Then, out of bit lines BL1 to BL8, one bit line to which a memory cell to write into or read from belongs to is selected.

In writing, a write current is made to flow across two drivers/sinkers connected to the selected one and the other of a pair of bit lines to which the selected memory cell is connected. As a result, data “1” or “0” is written to the MTJ element in the selected memory cell by the above-mentioned spin injection method.

In reading, a read current is made to flow across two drivers/sinkers connected to one and the other of a pair of bit lines to which the selected memory cell is connected. Then, the tunnel resistance of the MTJ element in the selected memory cell is recognized on the basis of the read current, such that data in the selected memory cell is read.

In addition, as in the manufacturing method described above, source/drain diffusion layers 4A, 4B of MIS transistors Tr1 to Tr10 may be formed in a self-aligning manner by ion implantation into the entire surface of the semiconductor substrate 1 using the gate electrode (word lines WL1 to WL8), in order to reduce and simplify the manufacturing process. In this case, diffusion layer (impurity region) 4C which does not contribute to the operation of the memory cell (cell groups) is formed in the active region between two word lines in the location where the word lines which are not connected to the cell groups on the active region pass on this active region.

Then, as shown in FIG. 4, word lines WL3, WL4 of cell group G2 serve as gate electrodes 3B, insulating film 2B serves as a gate insulating film, and diffusion layers 4A, 4C serve as source/drain regions. Thus, a parasitic transistor Tr′ is formed on active region AA2.

However, as described above, the word lines are selected one by one in the operation of the MRAM, so that at least one of two parasitic transistors Tr′ is always off. Therefore, in the present embodiment, there is no erroneous writing to or reading from MTJ elements J2, J5 connected to the parasitic transistors Tr′.

### [2] Second Embodiment

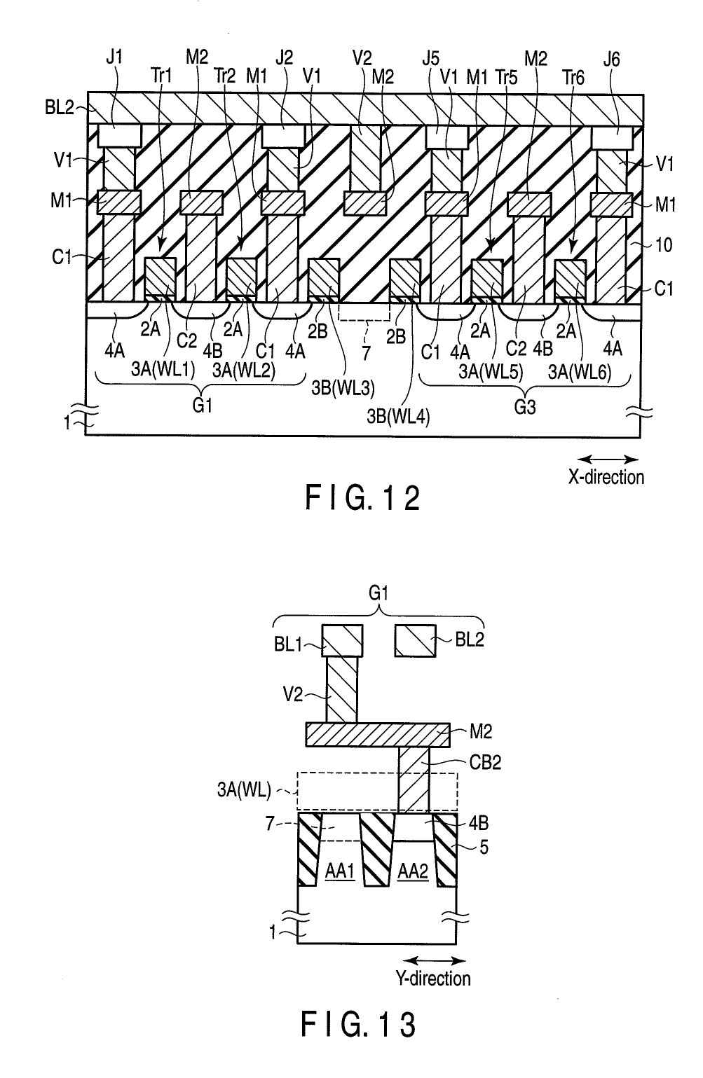

An MRAM according to a second embodiment of the present invention is described with reference to FIGS. 12 and 13. It should be noted that the layout of cell groups in the present embodiment is similar to the layout in the first embodiment and is therefore described with FIG. 3. Moreover, the same parts as in the first embodiment are provided with the same reference signs and are not described in detailed.

As described in the first embodiment, a plurality of active regions AA1 to AA4 have a striped structure extending in the X-direction, and therefore intersect word lines WL1 to WL8 extending in the Y-direction. Thus, in the process of manufacturing a memory cell array, not only MIS transistors Tr1 to Tr10 for switching elements constituting a memory cell MC but also parasitic transistors are formed at the same time in a plurality of locations where active regions AA1 to AA4 intersect word lines WL1 to WL8.

As described above, these parasitic transistors have no significant effect on the operation of the MRAM because at least one of the parasitic transistors is off. However, the one parasitic transistor may be on in some cases. Moreover, if a short channel effect becomes more obvious along with the advance in the miniaturization of the memory cells and cell groups, sufficient snapback resistance and cut-off characteristics of the parasitic transistors might not be ensured.

In the MRAM according to the first embodiment, the MIS transistors of different cell groups are provided on the same active region, so that if the snapback resistance and cut-off characteristics are not ensured, the write current/read current in operation may flow through channel regions of the parasitic transistors as a diverted current and flow into a nonselected cell in the same active region as the selected cell. This may cause wrong operation of the MRAM such as erroneous writing to or reading from the nonselected cell.

The MRAM according to the second embodiment of the present invention is characterized in that an impurity region 7 of a conductivity type opposite to the conductivity type of source/drain diffusion layers 4A, 4B is provided in the active region located between two word lines at the intersection of the active region which does not require the MIS transistor as a switch element and the word lines, for example, at the intersection of active region AA2 and the third and fourth word lines WL3, WL4 (gate electrodes 3B) shown in FIG. 12, and the intersection of the first active region AA1 and the first and second word lines WL1, WL2 (gate electrodes 3B) shown in FIG. 13.

Consequently, the MRAM of the present embodiment has a structure in which no parasitic transistors are formed in the location where the word line passes over the active region.

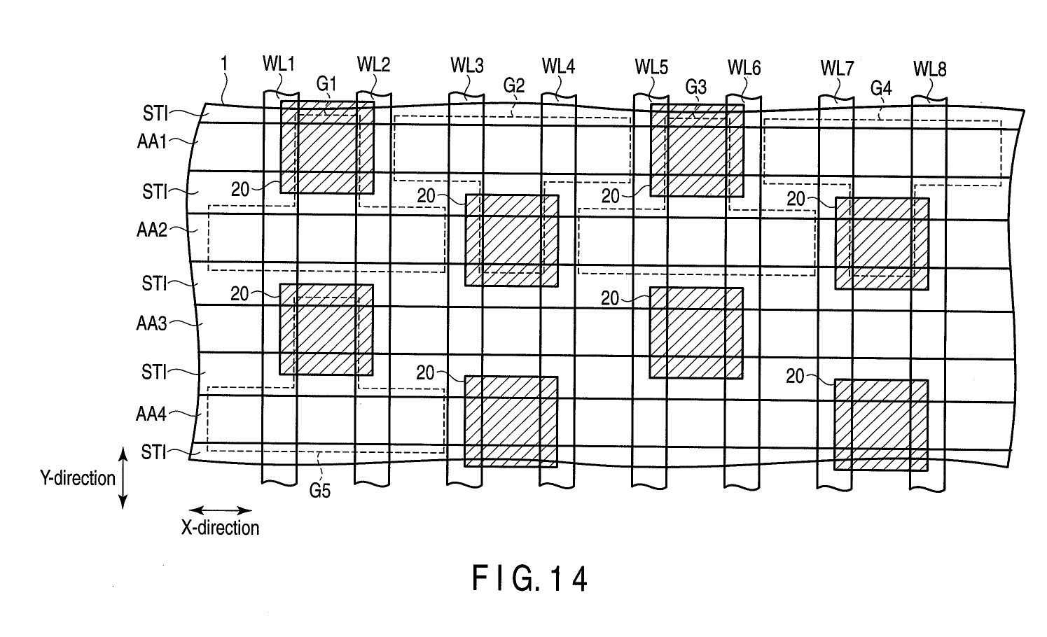

As in the present embodiment, when the conductivity type (second conductivity type) of source/drain diffusion layers 4A, 4B is N, the conductivity type of the impurity region 7 between word lines WL3, WL4 is P, so that the conductivity type of the region 7 may be the same as the conductivity type (first conductivity type) of a semiconductor substrate 1 or of a well region (not shown) in the semiconductor substrate 1. In this case, in the process of forming the source/drain diffusion layers, masks 20 are formed, as indicated by broken lines, in areas where the region 7 of the first conductivity type is provided as shown in, for example, FIG. 14, and ions are implanted into the semiconductor substrate 1. As a result, the impurity region 7 of the conductivity type opposite to the conductivity type of source/drain diffusion layers 4A, 4B is formed.

Therefore, as shown in, for example, FIG. 12, at the intersection of word lines WL3, WL4 (gate electrodes 3B) and the second active region AA2, there are two PN junctions composed of the N-type source/drain diffusion layer 4A and the P-type semiconductor substrate 1 (impurity region 7), that is, a structure in which two diodes are formed and their cathodes are connected together. This inhibits the diverted current of the write current/read current from flowing through the active region and being injected into the nonselected cell provided in the same active region.

Consequently, according to the second embodiment of the present invention, it is possible to provide a semiconductor memory capable of improving a process margin and also capable of inhibiting wrong operation.

### [3] Third Embodiment

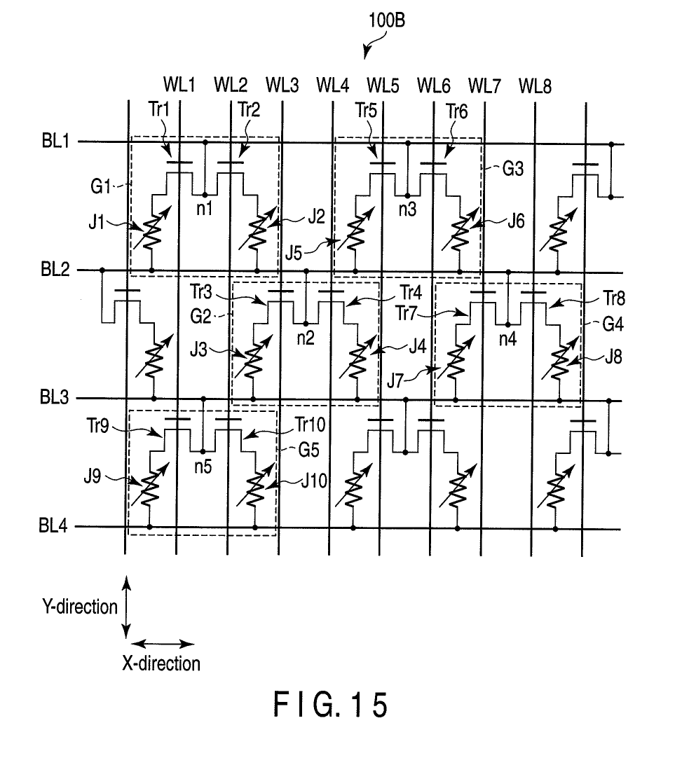

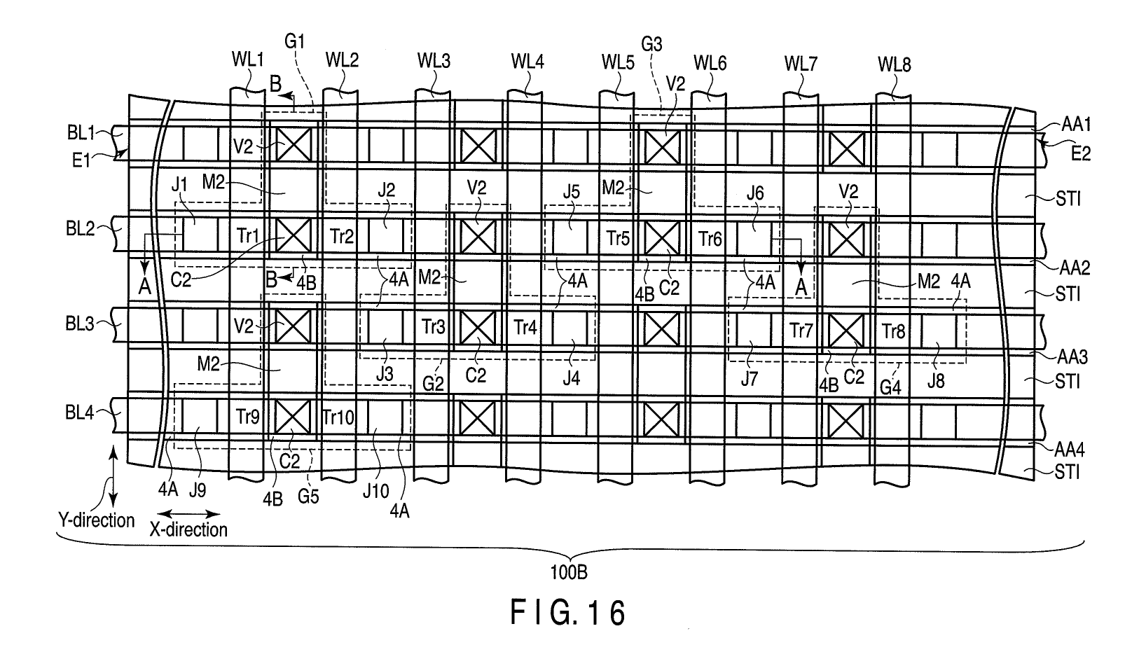

An MRAM according to a third embodiment of the present invention is described with reference to FIGS. 15 and 16. It should be noted that the same parts as in the first and second embodiments are provided with the same reference signs and are not described in detailed.

(1) Circuit Configuration

The circuit configuration of a memory cell array in the MRAM according to the third embodiment is described with FIG. 15.

When one cell group has the circuit configuration shown in FIG. 1, it is also possible to connect a plurality of cell groups in the circuit configuration of a memory cell array 100B shown in FIG. 15. In the memory cell array 100B shown in FIG. 15, the cell groups adjacent in the X-direction, the cell groups adjacent in the Y-direction and the cell groups adjacent in an oblique direction all have the translational relation.

The circuit configurations of cell groups G1 to G5 constituting the memory cell array 100B of the present embodiment are described below. In addition, the circuit configuration of Cell group G1 is similar to the circuit configuration in the first and second embodiments and is therefore not described in detail.

Cell group G3 adjacent to cell group G1 in the X-direction has the following circuit configuration. One end of a fifth MTJ element J5 is connected to one end of a current path of a fifth MIS transistor Tr5, and the other end of the fifth MTJ element J5 is connected to a second bit line BL2. The other end of the current path of the fifth MIS transistor Tr5 is connected to a node n3, and a gate of the fifth MIS transistor Tr5 is connected to a fifth word line WL5. One end of a sixth MTJ element J6 is connected to one end of a current path of a sixth MIS transistor Tr6, and the other end of the sixth MTJ element J6 is connected to the second bit line BL2. The other end of the current path of the sixth MIS transistor Tr6 is connected to node n3, and a gate of the sixth MIS transistor Tr6 is connected to a sixth word line WL6. Further, node n3 to which the fifth and sixth MIS transistors Tr5, Tr6 are connected is connected to a first bit line BL1.

Thus, cell groups G1, G3 adjacent in the X-direction are connected to the same pair of bit lines BL1, BL2 in the same manner. That is, shared node n1 of cell group G1 and shared node n3 of cell group G3 are both connected to the first bit line BL1. In this manner, cell groups G1, G3 adjacent in the X-direction have the translational relation.

Cell group G5 adjacent to cell group G1 in the Y-direction has the following circuit configuration. One end of a ninth MTJ element J9 is connected to one end of a current path of a ninth MIS transistor Tr9, and the other end of the ninth MTJ element J9 is connected to a fourth bit line BL4. The other end of the current path of the ninth MIS transistor Tr9 is connected to a node n5, and a gate of the ninth MIS transistor Tr9 is connected to the first word line WL1. One end of a tenth MTJ element J10 is connected to one end of a current path of a tenth MIS transistor Tr10, and the other end of the tenth MTJ element MTJ10 is connected to the fourth bit line BL4. The other end of the current path of the tenth MIS transistor Tr10 is connected to node n5, and a gate of the tenth MIS transistor Tr10 is connected to the second word line WL2. Further, node n5 to which the ninth and tenth MIS transistors Tr9, Tr10 are linked is connected to a third bit line BL3.

Thus, cell groups G1, G5 adjacent in the Y-direction share the same word lines WL1, WL2, and cell group G1 between the pair of bit lines BL1, BL2 and cell group G5 between the pair of bit lines BL3, BL4 are arranged in the same direction. Thus, bit line BL1 to which shared node n1 is connected, bit line BL2 to which MTJ elements J1, J2 are connected, bit line BL3 connected to shared node n5, and bit line BL4 to which MTJ elements J9, J10 are connected are arranged in order in the Y-direction of the memory cell array 100B. That is, in the Y-direction of the memory cell array, the bit lines to which the shared nodes are connected and the bit lines to which the MTJ elements are connected are alternately arranged along the Y-direction. Thus, cell groups G1, G5 adjacent in the Y-direction have the translational relation.

A second cell group G2 adjacent to cell group G1 in the oblique direction has the following circuit configuration. One end of a third MTJ element J3 is connected to one end of a current path of a third MIS transistor Tr3, and the other end of the third MTJ element J3 is connected to the third bit line BL3. The other end of the current path of the third MIS transistor Tr3 is connected to a node n2, and a gate of the third MIS transistor Tr3 is connected to a word line WL3. One end of a fourth MTJ element J4 is connected to one end of a current path of a fourth MIS transistor Tr4, and the other end of the fourth MTJ element J4 is connected to the third bit line BL3. The other end of the current path of the fourth MIS transistor Tr4 is connected to node n2, and a gate of the fourth MIS transistor Tr4 is connected to a fourth word line WL4. Further, node n2 to which the third and fourth MIS transistors Tr3, Tr4 are linked is connected to the second bit line BL2.

Thus, cell groups G1, G2 adjacent in the oblique direction are arranged so that cell group G1 between the pair of bit lines BL1, BL2 and cell group G2 between the pair of bit lines BL2, BL3 are in the same direction. Here, cell groups G1, G2 share bit line BL2, and MTJ elements J1, J2 of cell group G1 and shared node n2 of cell group G2 are connected to bit line BL2. Thus, cell groups G1, G2 adjacent in the oblique direction have the translational relation.

In addition, cell groups G1, G2 or cell groups G2, G3 adjacent in the oblique direction do not share the word line. Therefore, word lines WL3, WL4 used in cell group G2 merely pass between cell groups G1, G3 adjacent in the X-direction, and are not linked to either of cell groups G1, G3.

(2) Structure

FIG. 16 is a plan view showing the layout of the memory cell array 100B in the MRAM according to the third embodiment of the present invention. Sectional structures along the X- and Y-direction in the present embodiment are the same as either the sectional structures shown in the first embodiment (FIGS. 4 and 5) or the sectional structures shown in the second embodiment (FIGS. 12 and 13), and are therefore not described in detail.

Moreover, as shown in FIG. 16, the layout and configuration of cell groups G1, G3, G5 are similar to the layout and configuration shown in FIG. 3. Therefore, in the present embodiment, cell groups G1, G3, G5 are not described, and the configuration of a cell group G2 adjacent to cell group G1 in the oblique direction is only described.

The third and fourth MTJ elements J3, J4 in cell group G2 is provided under third bit line BL3. The third and fourth MIS transistors Tr3, Tr4 in cell group G2 is provided on a third active region AA 3. A source/drain diffusion layer (fourth source/drain diffusion layer) 4A of the third MIS transistor Tr3 is provided in active region AA3 under MTJ element J3, and connected to MTJ element J3 through an intermediate interconnection and a via contact. A source/drain diffusion layer (sixth source/drain diffusion layer) 4A of the fourth MIS transistor Tr4 is provided in active region AA3 under MTJ element J4, and connected to MTJ element J4 through an intermediate interconnection and a via contact.

A source/drain diffusion layer (fifth source/drain diffusion layer) 4B shared by the two MIS transistors Tr3, Tr4 is connected to a leader interconnection M2 through a contact C2. The leader interconnection M2 is connected to the second bit line BL2 through a via contact V2.

Gate electrodes of MIS transistors Tr3, Tr4 extend in the Y-direction, and are shared by cell group G2 and cell group adjacent thereto in the Y-direction. That is, the gate electrode of MIS transistors Tr3, Tr4 functions as the third and fourth word lines WL3, WL4. The third and fourth word lines WL3, WL4 pass between two cell groups G1, G3 adjacent in the X-direction, and intersect active regions AA1, AA2.

Cell group G4 has a configuration substantially equal to that of cell group C2 located adjacently thereto in the X-direction, and is connected to the bit lines BL2, BL3 and seventh and eighth MTJ elements J7, J8. Seventh and eighth MIS transistors Tr7, Tr8 in cell group G4 are located above active region AA3, and their gate electrodes functions as the seventh and eighth word lines WL7, WL8. Source/drain diffusion layer 4B shared by the two MIS transistors Tr7, Tr8 is provided in active region AA3, and its diffusion layer 4A is connected to bit line BL2 through the leader interconnection M2.

Source/drain diffusion layer 4A of the seventh MIS transistor Tr7 is connected to the seventh MTJ element J7. Source/drain diffusion layer 4A of MIS transistor Tr8 is connected to the eighth MTJ element J8. The two MTJ elements J7, J8 are provided under the bit line BL3, and directly connected to the bit line BL3.

Word lines WL4, WL5 pass between cell group G2 and cell group G4 adjacent in the X-direction.

In the layout of the memory cell array 100B shown in FIG. 16, the size of one memory cell is also 8F².

The MRAM according to the present embodiment is characterized in that active regions AA1 to AA4 where the memory cells and the cell groups are provided have a striped structure as in the first and second embodiments. Thus, a surface region of a semiconductor substrate 1 has a line-and-space pattern, and the patterning and fabrication of the active regions are easier.

Consequently, according to the third embodiment of the present invention, it is also possible to provide a semiconductor memory capable of improving a process margin.

In addition, a method of manufacturing the memory cell array 100B in the MRAM according to the present embodiment is substantially equal to that of the memory cell array 100A in the first and second embodiments, and is therefore not described. Read/write operations for the memory cell array 100B in the MRAM according to the present embodiment are substantially equal to the read/write operations for the memory cell array 100A in the first and second embodiments, and are therefore not described.

3. Others

According the embodiments of the present invention, it is possible to provide a semiconductor memory capable of improving a process margin.

While the MRAM has been described as an example of the semiconductor memory in the embodiments of the present invention, the present invention is not limited thereto. Instead of the magnetoresistive element, the present invention is also applicable to other resistive storage elements such as a PCRAM with a storage element that uses the change of a crystalline phase, or an ReRAM with a storage element that utilizes its resistance greatly changed by the application of a voltage. In such a case as well, effects similar to the effects described in the embodiments of the present invention are obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory comprising:
first and second adjacent bit lines extending in a first direction and provided in the same interconnect layer;
an active region extending in the first direction and provided in a memory cell array;
first and second adjacent word lines extending in a second direction intersecting the first direction;
a first transistor having first and second source/drain diffusion layers provided in the active region, a first gate insulating film provided on the surface of the active region between the first and second source/drain diffusion layers, and a first gate electrode connected to the first word line and provided on the first gate insulating film;
a second transistor having the second source/drain diffusion layer shared with the first transistor, a third source/drain diffusion layer provided in the active region, a second gate insulating film provided on the surface of the active region between the second and third source/drain diffusion layers, and a second gate electrode connected to the second word line and provided on the second gate insulating film;
a first resistive storage element which has one end connected to the second bit line and the other end connected to the first source/drain diffusion layer and which is provided under the second bit line above the first source/drain diffusion layer;
a second resistive storage element which has one end connected to the second bit line and the other end connected to the third source/drain diffusion layer and which is provided under the second bit line above the third source/drain diffusion layer; and
an intermediate interconnection which is connected to the first bit line and the second source/drain diffusion layer and which is disposed between the first and second word lines across the first and second bit lines,
wherein the active region has a striped structure extending in the first direction, and extends from one end of the memory cell array to the other.

2. The semiconductor memory according to claim 1, wherein
each of the first and second resistive storage elements is a magnetoresistive effect element.

3. The semiconductor memory according to claim 2, wherein
the magnetoresistive effect element has a magnetization invariable layer having an invariable direction of magnetization, a magnetization free layer having a variable direction of magnetization, and a nonmagnetic layer provided between the magnetization invariable layer and the magnetization free layer.

4. The semiconductor memory according to claim 1, wherein
the active region is positioned to vertically overlap the second bit line.

5. The semiconductor memory according to claim 1, wherein
the active region is interposed between two striped insulating films which are provided in the memory cell array and which extend in the first direction.

6. The semiconductor memory according to claim 1, wherein
the gate electrodes of the first and second transistors extend in the second direction, and function as the first and second word lines, respectively.

7. A semiconductor memory comprising:
first and second bit lines extending in a first direction and adjacently provided in the same interconnection layer;
first and second active regions having a striped structure extending in the first direction and adjacently provided in a semiconductor substrate;
first and second adjacent word lines extending in a second direction intersecting the first direction;
a first transistor having first and second source/drain diffusion layers provided in the second active region, a first gate insulating film provided on the surface of the second active region between the first and second source/drain diffusion layers, and a first gate electrode connected to the first word line and provided on the first gate insulating film;
a second transistor having the second source/drain diffusion layer shared with the first transistor, a third source/drain diffusion layer provided in the second active region, a second gate insulating film provided on the surface of the second active region between the second and third source/drain diffusion layers, and a second gate electrode connected to the second word line and provided on the second gate insulating film;
a first resistive storage element which has one end connected to the second bit line and the other end connected to the first source/drain diffusion layer and which is provided under the second bit line above the first source/drain diffusion layer;
a second resistive storage element which has one end connected to the second bit line and the other end connected to the third source/drain diffusion layer and which is provided under the second bit line above the third source/drain diffusion layer;
a first intermediate interconnection which is connected to the first bit line and the second source/drain diffusion layer and which is disposed between the first and second word lines over the first and second active regions;
third and fourth adjacent word lines extending in a direction intersecting the first and second active regions;
a third transistor having fourth and fifth source/drain diffusion layers provided in the first active region, a third gate insulating film provided on the surface of the first active region between the fourth and fifth source/drain diffusion layers, and a third gate electrode connected to the third word line and provided on the third gate insulating film;
a fourth transistor having the fifth source/drain diffusion layer shared with the third transistor, a sixth source/drain diffusion layer provided in the first active region, a fourth gate insulating film provided on the surface of the first active region between the fifth and sixth source/drain diffusion layers, and a fourth gate electrode connected to the fourth word line and provided on the fourth gate insulating film;
a third resistive storage element which has one end connected to the first bit line and the other end connected to the fourth source/drain diffusion layer and which is provided under the first bit line above the fourth source/drain diffusion layer;
a fourth resistive storage element which has one end connected to the first bit line and the other end connected to the sixth source/drain diffusion layer and which is provided under the first bit line above the sixth source/drain diffusion layer; and
a second intermediate interconnection which is connected to the second bit line and the fifth source/drain diffusion layer and which is disposed between the third and fourth word lines over the first and second active regions.

8. The semiconductor memory according to claim 71 wherein
an impurity region of a conductivity type opposite to a conductivity type of the source/drain diffusion layers is provided in the second active region between the third and fourth word lines at the intersection of the third and fourth word lines and the second active region.

9. The semiconductor memory according to claim 7, wherein
each of the first and second resistive storage elements is a magnetoresistive effect element.

10. The semiconductor memory according to claim 9, wherein
the magnetoresistive effect element has a magnetization invariable layer having an invariable direction of magnetization, a magnetization free layer having a variable direction of magnetization, and a nonmagnetic layer provided between the magnetization invariable layer and the magnetization free layer.

11. The semiconductor memory according to claim 7, wherein
the first active region is disposed under the first bit line, and the second active region is disposed under the second bit line.

12. The semiconductor memory according to claim 7, wherein
a striped insulating film extending in the first direction is provided in the semiconductor substrate between the first active region and the second active region.

13. The semiconductor memory according to claim 7, wherein
the gate electrodes of the first to fourth transistors extend in the second direction, and function as the first to fourth word lines, respectively.

14. A semiconductor memory comprising:
first and second bit lines extending in a first direction and adjacently provided in the same interconnection layer;
first and second active regions having a striped structure extending in the first direction and adjacently provided in a semiconductor substrate;
first and second adjacent word lines extending in a second direction intersecting the first direction;
a first transistor having first and second source/drain diffusion layers provided in the second active region, a first gate insulating film provided on the surface of the second active region between the first and second source/drain diffusion layers, and a first gate electrode connected to the first word line and provided on the first gate insulating film;
a second transistor having the second source/drain diffusion layer shared with the first transistor, a third source/drain diffusion layer provided in the second active region, a second gate insulating film provided on the surface of the second active region between the second and third source/drain diffusion layers, and a second gate electrode connected to the second word line and provided on the second gate insulating film;
a first resistive storage element which has one end connected to the second bit line and the other end connected to the first source/drain diffusion layer and which is provided under the second bit line above the first source/drain diffusion layer;
a second resistive storage element which has one end connected to the second bit line and the other end connected to the third source/drain diffusion layer and which is provided under the second bit line above the third source/drain diffusion layer;
a first intermediate interconnection which is connected to the first bit line and the second source/drain diffusion layer and which is disposed between the first and second word lines over the first and second active regions;
a third bit line which is provided in the same interconnect layer as the first and second bit lines and which extends in the first direction and which is adjacent to the second bit line;
a third active region which has striped structure extending in the first direction and which is provided in the semiconductor substrate adjacently to the second active region;
third and fourth adjacent word lines extending in the second direction;
a third transistor having fourth and fifth source/drain diffusion layers provided in the third active region, a third gate insulating film provided on the surface of the third active region between the fourth and fifth source/drain diffusion layers, and a third gate electrode connected to the third word line and provided on the third gate insulating film;
a fourth transistor having the fifth source/drain diffusion layer shared with the third transistor, a sixth source/drain diffusion layer provided in the third active region, a fourth gate insulating film provided on the surface of the third active region between the fifth and sixth source/drain diffusion layers, and a fourth gate electrode connected to the fourth word line and provided on the fourth gate insulating film;
a third resistive storage element which has one end connected to the third bit line and the other end connected to the fourth source/drain diffusion layer and which is provided under the third bit line above the fourth source/drain diffusion layer;
a fourth resistive storage element which has one end connected to the third bit line and the other end connected to the sixth source/drain diffusion layer and which is provided under the third bit line above the sixth source/drain diffusion layer; and
a second intermediate interconnection which is connected to the second bit line and the fifth source/drain diffusion layer and which is disposed between the third and fourth word lines over the second and third active regions.

15. The semiconductor memory according to claim 14, wherein
an impurity region of a conductivity type opposite to a conductivity type of the source/drain diffusion layers is provided in the second active region between the third and fourth word lines at the intersection of the third and fourth word lines and the second active region.

16. The semiconductor memory according to claim 14, wherein
each of the first to fourth resistive storage elements is a magnetoresistive effect element.

17. The semiconductor memory according to claim 16, wherein
the magnetoresistive effect element has a magnetization invariable layer having an invariable direction of magnetization, a magnetization free layer having a variable direction of magnetization, and a nonmagnetic layer provided between the magnetization invariable layer and the magnetization free layer.

18. The semiconductor memory according to claim 14, wherein
the first to third active regions are positioned in the semiconductor substrate to vertically overlap the first to third bit lines, respectively.

19. The semiconductor memory according to claim 14, wherein
striped insulating films extending in the first direction are provided in the semiconductor substrate between the first active region and the second active region and in the semiconductor substrate between the second active region and the third active region, respectively.

20. The semiconductor memory according to claim 14, wherein
the gate electrodes of the first to fourth transistors extend in the second direction, and function as the first to fourth word lines, respectively.
